(19) United States
(12) Patent Application Publication
(10) Pub. No.: US 2005/0124129 A1
(43) Pub. Date: Jun. 9, 2005

(54) Method of fabrication of silicon-gate MIS transistor

(76) Inventor: Takayuki Ito, Kawasaki-shi (JP)

Correspondence Address: Finnegan, Henderson, Farabow,;Garrett & Dunner, L.L.P., 1300 I Street, N.W., Washington, DE, 20005-3315, US

(21) Appl. No.: 10/960,086

(22) Filed: Oct. 8, 2004

(30) Foreign Application Priority Data
Oct. 10, 2003 (JP) P2003-351686

(51) Int. Cl. H01L 21/00; H01L 21/8234; H01L 21/324; H01L 21/42

(52) U.S. Cl. 438/308; 438/199; 438/795

(57) ABSTRACT

Disclosed is a method for manufacturing a semiconductor device, the method includes forming an insulator layer on a crystalline silicon substrate; forming selectively a silicon layer on the insulator layer, the silicon layer being lower in degree of crystallinity relative to the substrate; implanting impurity ions to surfaces of the substrate and the silicon layer so as to form impurity regions in the substrate in a self-aligned manner, generating a light pulse substantially having a wavelength in a range between 370 and 700 nm; and forming source and drain regions, and a silicon-gate electrode, through activation of implanted ions in the impurity regions and in the silicon layer, respectively, by common irradiation of the light pulse to the surfaces of the substrate and the silicon layer.

### CROSS REFERENCE TO RELATED APPLICATIONS

This application is based upon and claims the benefit of priority from prior Japanese Patent Application P2003-351686 filed on Oct. 10, 2003, and the entire contents thereof are incorporated herein by reference.

### BACKGROUND OF THE INVENTION

1. Field of the Invention

The present invention relates to a fabrication method for a semiconductor device. More specifically, the present invention relates to a fabrication method for a silicon-gated metal-insulator-semiconductor (MIS) transistor.

2. Description of the Related Art

Increase in the integrated density or miniaturization of the elements improves performance of a semiconductor device, such as an LSI. Accordingly, integrated circuits made by such elements have become more and more largely integrated, and miniaturization of the elements further advances.

Reduction in element dimensions accompanies further importance of formation of a shallower p-n junction. For example, one of the methods of forming a shallow impurity-diffused region is the optimization of ion implantation with low acceleration energy and subsequent annealing.

Nevertheless, in the case of ion implantation of boron (B), which is conventionally used as a p-type dopant, and phosphorus (P) or arsenic (As) as an n-type dopant, the diffusion coefficients thereof are large in a silicon (Si) substrate. Therefore, once rapid thermal annealing (RTA) using a halogen lamp, which represents the annealing methods, is performed, impurities diffuse in and out of a region where dopant has been implanted. As a result, an impurity profile cannot be controlled accurately. In addition, when the annealing temperature is reduced to control impurity diffusion, high-density activation of impurities cannot be expected. Accordingly, it is difficult to form a shallow junction depth (approximately 20 nm or less) with low resistivity by the conventional annealing using a halogen lamp.

Recently, flash lamp annealing (FLA) using a xenon (Xe) flash lamp has been considered as an alternative annealing method. A Xe flash lamp has Xe gas sealed in a tube such as a quartz tube, and can emit white lights ranging between, for example, several 100 msec and several 100 nsec by discharging electric charges stored in a condenser or the like for a short period of time. Accordingly, since usage of a flash lamp allows extremely short-time high-temperature processing, it is expected to be effective to form source and drain regions.

However, silicon gate MIS transistors, which have been extensively developed in recent years, have to avoid depletion of the gates also, by sufficiently diffusing the impurities doped in the gate electrodes. If there is a doped layer insufficiently concentrated in a gate electrode, this may bring about depletion of carriers in the gate, resulting in reduction of the capacitance of the gate capacitor. The driving performance of the transistor may also reduce. Since the flash lamp annealing method is an extremely short-time heat treatment, it may be further disadvantageous for impurity diffusion within gate electrodes. Therefore, it has been difficult to fabricate finely structured, high-performance transistors.

In addition, since the flash lamp annealing is a quick temperature increase and decrease process, high thermal stress is applied to the semiconductor substrate. There are also differences in heating efficiency, depending on the types of film of element patterns. For these reasons, when annealing a semiconductor substrate in which fine element patterns with convexity and concavity made of various materials are formed, there is a fear of causing the substrate to be damaged with slip, defects, or the like.

Japanese Patent Application Laid-Open No. H9-190983 discloses a method of fabrication for a MOSFET with a silicon gate structure or a method to suppress development of gate depletion by heating for a short time using RTA as a final annealing. However, there is no disclosure or any teaching regarding an effective method of fabricating silicon gate MIS transistors having source and drain regions with a depth of several ten nanometers, which allows both the provision of depletion layer-controlled silicon gate electrodes and the formation of shallow source and drain regions.

### SUMMARY OF THE INVENTION

An aspect of the present invention inheres in a method for manufacturing a semiconductor device, the method including forming an insulator layer on a crystalline silicon substrate; forming selectively a silicon layer on the insulator layer, the silicon layer being lower in degree of crystallinity relative to the substrate; implanting impurity ions to surfaces of the substrate and the silicon layer so as to form impurity regions in the substrate in a self-aligned manner, generating a light pulse substantially having a wavelength in a range between 370 and 700 nm; and forming source and drain regions, and a silicon-gate electrode, through activation of implanted ions in the impurity regions and in the silicon layer, respectively, by common irradiation of the light pulse to the surfaces of the substrate and the silicon layer.

Another aspect of the present invention resides in a method for manufacturing a semiconductor device, the method including forming an insulator layer on a crystalline silicon substrate; forming selectively a silicon layer on the insulator layer, the silicon layer being lower in degree of crystallinity relative to the substrate; implanting impurity ions to surfaces of the substrate and the silicon layer so as to form impurity regions in the substrate in a self-aligned manner; generating a light pulse from a flash lamp light, by relative reduction of energy of the flash lamp light, in a wavelength of 370 n=or less, relative to the wavelength larger than 370 nm; and forming source and drain regions and a silicon-gate electrode, through activation of impurity ions in the impurity regions and in the silicon layer, respectively, by common irradiation of the light pulse to the surfaces of the substrate and the silicon layer.

Yet another aspect of the present invention resides in a method for manufacturing a semiconductor device, the method including forming on a substrate an insulator layer and a silicon layer on the insulator layer, the substrate being made of crystalline silicon and the silicon layer being lower in degree of crystallinity relative to the substrate forming a doped-silicon gate structure by implanting impurity ions to the silicon layer, activation of implanted ions and selective etching of the silicon layer and the insulator layer, implanting impurity ions to a surface of the substrate so as to form impurity regions in the substrate in a self-aligned manner; and forming source and drain regions through activation of the implanted ions in the impurity regions by irradiation of a light pulse to the surface of the substrate.

### BRIEF DESCRIPTION OF THE DRAWINGS

FIG. 1A-FIG. 1D are cross-sectional views showing a semiconductor device fabrication process according to the first embodiment of the present invention;

FIG. 2A-FIG. 2D are cross-sectional views showing the semiconductor device fabrication process according to the first embodiment of the present invention;

FIG. 3A and FIG. 3B show relationships between the gate voltage (V) and the gate capacitance (F/cm²) of the respective MOS capacitors of Example 1 and Comparative Example 1;

FIG. 3C shows a circuit for the C-V measurement of the MOS capacitor;

FIG. 4 shows boron (B) concentration distributions in the respective gate electrodes of Example 1 and Comparative Example 1;

FIG. 5 shows boron (B) concentration distributions in the respective silicon semiconductor substrates of Example 1 and Comparative Example 1;

FIG. 6 shows a process window for a substrate preheating temperature and the irradiation energy of a Xe flash lamp light when irradiating a flash lamp light via an attached, wavelength selecting optical filter according to the first embodiment;

FIG. 7 shows a process window for a substrate preheating temperature and the irradiation energy of a Xe flash lamp light when irradiating a flash lamp light without attaching a wavelength selecting optical filter;

FIG. 8 shows a spectrum of a Xe flash lamp;

FIG. 9 is a graph showing dependency of a silicon extinction coefficient spectrum on crystallinity;

FIG. 10 is a conceptual diagram showing locations of hot spots where light energy concentrates, which are generated due to interference when a single-wavelength light refracts at polycrystalline silicon gates and STIs;

FIG. 11A-FIG. 11D are cross-sectional views showing a MIS transistor fabrication method according to the second embodiment of the present invention;

FIG. 12A-FIG. 12D are cross-sectional views showing the MIS transistor fabrication method according to the second embodiment of the present invention;

FIG. 13A-FIG. 13C show cross-sectional views showing the MIS transistor fabrication method according to the second embodiment of the present invention;

FIG. 14A and FIG. 14B show relationships of a gate voltage and the gate capacitance of the respective MOSFETs manufactured in Example 2 and Comparative Example 3;

FIG. 15A and FIG. 15B show impurity profiles along the respective depths of the polycrystalline silicon gate electrodes formed in Example 2 and Comparative Example 3;

FIG. 16A and FIG. 16B show impurity profiles along the respective depths of the monocrystalline silicon semiconductor substrate when sources and corresponding drain regions are formed by Example 2 and an RTA process using a halogen lamp, respectively;

FIG. 17 shows a desirable annealing condition to diffuse and activate impurities implanted in a polycrystalline silicon layer; and

FIG. 18 shows a desirable annealing condition to suppress the diffusion of and activate impurities implanted in a monocrystalline silicon semiconductor substrate.

### DETAILED DESCRIPTION OF THE EMBODIMENTS

One aspect of the present invention is an optically heating method using a high-luminance light source of forming a shallow impurity-diffused region with low resistivity in a semiconductor substrate while controlling development of gate electrode depletion. Embodiments of the present invention are described forthwith while referring to the attached drawings. Note that a pulse width means a width at half the energy unless otherwise defined.

(FIRST EMBODIMENT)

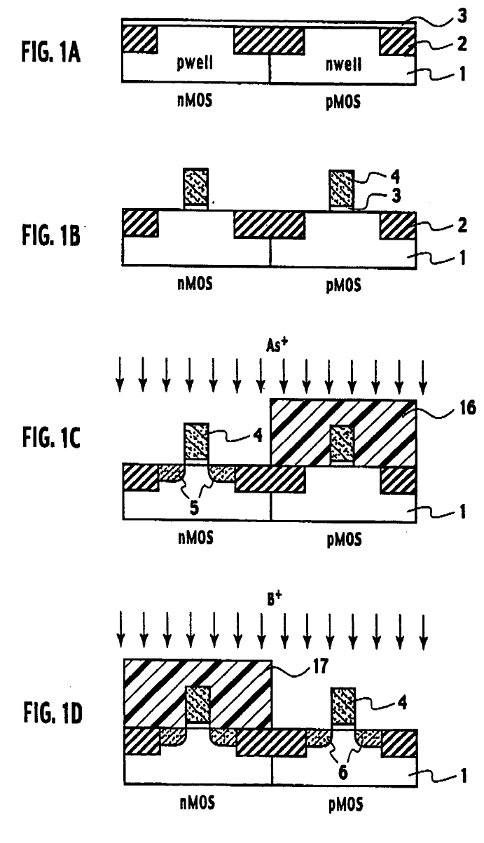

As shown in FIG. 1A, a p-well region (p well) is formed in an nMOS region of a silicon semiconductor substrate 1 using an ordinary CMOS transistor fabrication method; an n-well region (n well) is formed in a pMOS region; and device isolator regions 2 such as silicon oxide filled shallow trench isolations (STIs) are formed. Afterwards, a gate insulator layer 3 such as a silicon oxide layer is formed upon the entire surface of the semiconductor substrate 1.

Furthermore, a polycrystalline silicon layer 4 is formed upon the gate insulator layer 3. In this case, a typical film thickness of the polycrystalline silicon layer 4 is between 100 nm and 200 nm. Subsequently, the polycrystalline silicon layer 4 and the gate insulator layer 3 are selectively etched using a highly directive etching method, such as reactive ion etching (RIE), thereby forming a structure as shown in FIG. 1B where the polycrystalline silicon layers 4 and the gate insulator layers 3 are selectively formed.

As shown in FIG. 1C, a photoresist film 16 is formed on the pMOS region. Ions of group-V atoms such as arsenic ion (As⁺) to be used as n-type impurity ions are implanted in the nMOS region of the semiconductor substrate 1 using as a mask the polycrystalline silicon layer 4, which has been selectively formed on the nMOS region (First Ion Implantation in nMOS region). Shallow impurity regions 5 are formed adjacent to corresponding polycrystalline silicon layer 4 in the surface area of the semiconductor substrate 1 through the first ion implantation.

As shown in FIG. 1D, a photoresist film 17 is formed on the nMOS region after removal of the photoresist film 16. Ions of group-E atoms such as boron ion (B⁺) to be used as p-type impurity ions are implanted in the pMOS region of the semiconductor substrate 1 using as a mask the polycrystalline silicon layer 4, which has been selectively formed on the pMOS region (First Ion Implantation in pMOS region). Shallow impurity regions 6 are formed adjacent to corresponding polycrystalline silicon layer 4 in the surface area of the semiconductor substrate 1 through the first ion implantation.

After removal of the photoresist film 17, the semiconductor substrate 1 is preheated, keeping a certain fixed temperature. Halogen lamp heating or hot plate heating may be available as the preheating method. It is desirable that the preheated temperature be specified between 300° C. and 600° C. It is undesirable that the preheated temperature exceed 600° C. because impurity diffusion and/or secondary defects may develop.

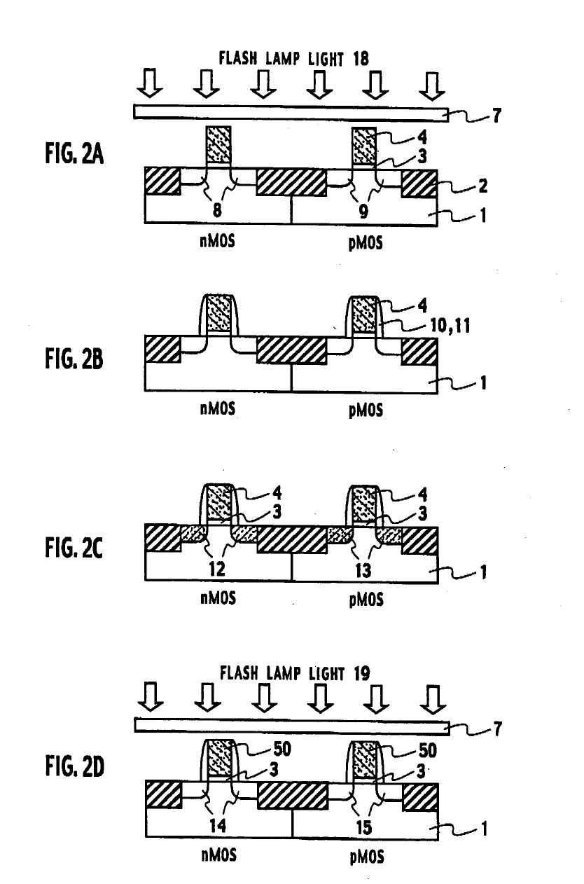

As shown in FIG. 2A, light 18 emitted from a flash lamp through a wavelength selecting optical filter 7 irradiates the surface of the semiconductor substrate 1 while keeping the semiconductor substrate 1 at a certain fixed temperature (first annealing). It is preferable to use a xenon (Xe) flash lamp as the flash lamp.

It is desirable that the wavelength selecting optical filter 7, which is deployed between the flash lamp and the semiconductor substrate 1, be an optical filter which allows cutting off short wavelength lights of 300 nm or less. More desirably, the wavelength selecting optical filter 7 is an optical filter that allows cutting off short wavelength lights of 400 nm or less.

It is desirable that the pulse width of the light 18 be between 0.1 millisecond and 100 milliseconds. More preferably, the pulse width is between one millisecond and ten milliseconds. Typically, the light 18 irradiates the semiconductor substrate 1 once. An irradiation energy density of the light 18 (energy density that reaches the surface of the semiconductor substrate 1) is specified to be approximately 100 J/cm² or less. It is undesirable that the irradiation energy density exceeds 100 J/cm² because in such a large energy density diffusion of impurity atoms may advance and/or thermal stress that will be created inside the silicon substrate 1 increases and this may lead to damage of the substrate 1 such as slip and breakage.

The first annealing may be carried out by RTA using a halogen lamp. When using a halogen lamp, it is desirable that annealing conditions be a substrate temperature of 900° C. or less and an annealing time period of 30 seconds or less.

The first annealing activates the impurity ions implanted in the semiconductor substrate 1 without deeply diffusing them, and repairs crystal defects in impurity regions 5 of the p-well region and in the impurity regions 6 of the n-well region. As a result, a shallow source and a drain region 8 (extension region) with n-type conductivity and a source and a drain region 9 (extension region) with p-type conductivity are formed adjacent to corresponding selectively formed polycrystalline silicon layers 4.

After forming the shallow source and drain regions 8 and 9, a silicon nitride (Si₃N₄) film 10 and a silicon oxide (SiO₂) film 11 are deposited in order upon the entire surface of the semiconductor substrate 1 using a film formation method such as low pressure chemical vapor deposition (LPCVD), covering the selectively formed polycrystalline silicon layers 4. Subsequently, the silicon nitride film 10 and the silicon oxide film 11 are etched using a highly directive etching method, such as RIE, thereby selectively leaving the silicon nitride film 10 and the silicon oxide film 11 only on the sidewalls of the polycrystalline silicon layers 4. As a result, multilayer sidewall spacers each made up of a silicon nitride film 10 and a silicon oxide film 11 as shown in FIG. 2 are formed.

Ions of group-V atoms such as phosphorus ions (P⁺) to be used as n-type impurity ions are implanted in the nMOS region using as a mask the selectively formed polycrystalline silicon layer 4 and the sidewall spacer made up of the silicon nitride film 10 and the silicon oxide film 11 (Second Ion Implantation in nMOS region). Ions of group-m atoms such as boron ions (B⁺) to be used as retype impurity ions are implanted in the pMOS region (Second Ion Implantation in pMOS region). The second Ion implantation may be carried out in the same way as with the case of the first ion implantation in which respective ions are implanted using as a mask a photoresist film delineated on the respective regions. As shown in FIG. 2C, the second ion implantation forms deep impurity regions 12 and 13 at certain intervals from the edges of corresponding gate insulator layer 3. At this time, P⁺ ions are also implanted in the polycrystalline silicon layer 4 for the nMOS region while B⁺ ions are implanted in polycrystalline silicon layer 4 for the pMOS region.

The semiconductor substrate 1 is preheated again, keeping a certain fixed temperature. It is desirable that the preheated temperature be specified between 300° C. and 6000C. It is undesirable that the preheated temperature exceeds 600° C. because impurity atoms may diffuse and/or secondary defects may grow.

As shown in FIG. 2D, light 19 emitted from a flash lamp (not shown) irradiates the entire surface of the semiconductor substrate 1 via the wavelength selecting optical filter 7 while maintaining the preheated temperature (Second Annealing). It is preferable to use a xenon (Xe) flash lamp as the flash lamp.

It is desirable that the wavelength selecting optical filter 7, which is deployed between the flash lamp and the semiconductor substrate 1, be an optical filter which allows cutting off short wavelength lights of 300 nm or less. More desirably, the wavelength selecting optical filter 7 is an optical filter which allows cutting off short wavelength lights of 400 nm or less.

It is desirable that the pulse width of the flash lamp light 19 be between 0.1 millisecond and 100 milliseconds. More preferably, the pulse width is between one millisecond and ten milliseconds. It is undesirable that the pulse width be short because sufficient repair of crystal defects in impurity regions may not be expected. It is also undesirable that the pulse width be long because of the enhancement of impurity atom diffusivity. Typically, the light 19 radiates once. An irradiation energy density of the light 19 (energy density that reaches the surface of the semiconductor substrate 1) is specified to be approximately 100 J/cm² or less. It is undesirable that the irradiation energy density exceeds 100 J/cin because the diffusion of impurity atoms may be enhanced and/or thermal stress created in the silicon substrate 1 increase, and this may lead to damage such as slip and breakage.

The second annealing activates ion-implanted impurity atoms and repairs crystal defects of the impurity regions 12 and 13. In addition, the impurity atoms in the selectively formed polycrystalline silicon layers 4 diffuse reaching the bottoms thereof. As a result, the polycrystalline silicon layers 4 have high conductivity. In this manner, as shown in FIG. 2D, deep source and drain regions 14 and 15 at certain intervals from the edges of corresponding gate electrode 50 and corresponding gate insulator layer 3 are formed.

Subsequent steps are not shown in the drawings; however, a silicon oxide film is formed on the entire surface of the substrate 1 as an interlayer insulator film at a film formation temperature of 400° C. using atmospheric pressure CVD, for example. Subsequently, contact holes are opened on the interlayer insulator film to form a source and a drain electrode, a gate electrode, an interconnect, and/or the like.

According to the MIS transistor fabrication method of the first embodiment of the present invention, usage of the wavelength selecting optical filter 7 allows formation of shallow impurity-diffused regions 8 and 9 with low resistivity while controlling development of depletion of carriers in the gate electrodes 40, also allows sufficient diffusion and activation of impurities in the gate electrodes 40 formed on the semiconductor substrate 1, and accurate control of impurity profiles. This allows stable and easy fabrication of high-performance, miniaturized MIS transistors.

### EXAMPLE 1

The first embodiment can be implemented under the following conditions:
(1) FIRST ION IMPLANTATION
   nMOS region: AS⁺, acceleration energy: 1 keV, dose amount 1×10¹⁵ cm²
   pMOS region: B⁺, acceleration energy: 0.2 keV dose amount: 1×10¹⁵ cm⁻²
(2) SECOND ION IMPLANTATION
   nMOS region: P⁺, acceleration energy: 15 keV, dose amount: 3×10¹⁵ cm⁻²
   pMOS region: B⁺, acceleration energy: 4 keV, dose amount: 3×10¹⁵ cm⁻²
(3) FIRST AND SECOND ANNEALING
   Preheating temperature: 450° C.
   Light source: xenon flash lamp
   Pulse width of light 1 millisecond
   Irradiation energy density: 35 J/cm²

The wavelength selecting optical filter 7 used removes energy portion that resides in the wavelength of 300 nm or less from the light 18, 19 originally emitted from the xenon flash lamp light source. The film thickness of the gate electrode 50 was 175 m.

### COMPARATIVE EXAMPLE 1

A MOS transistor was fabricated under the same conditions such as an irradiation energy density as those in Example 1 except that the wavelength selecting optical filter 7 was not used.

### COMPARATIVE EXAMPLE 2

A MOS transistor was fabricated under the same conditions as those with Comparative Example 1 except that the irradiation energy density was specified to be 45 J/cm².

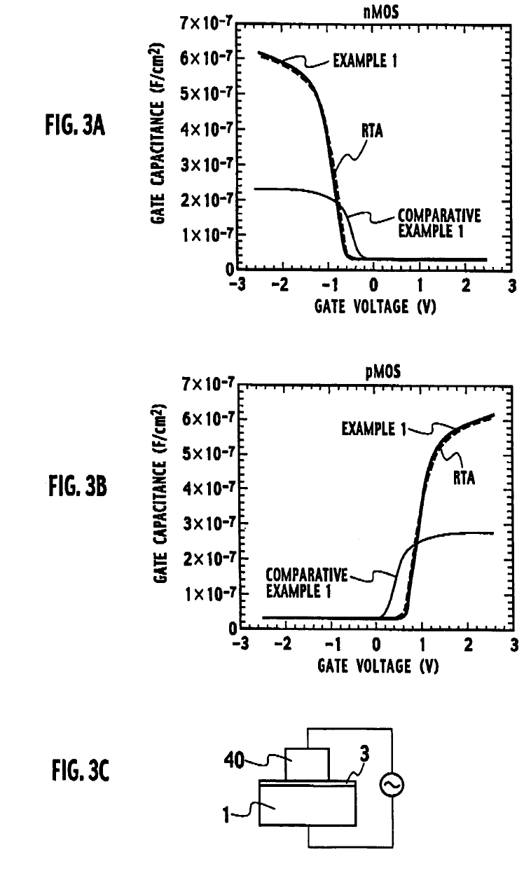

FIG. 3A and FIG. 3B are graphs that show dependency of a gate capacitance on the gate voltage in respective MOS transistors fabricated in Example 1 and Comparative Example 1. The horizontal axis indicates the gate voltage (V) and the vertical axis indicates the gate capacitance (F/cm²). FIG. 3A and FIG. 3B also show the corresponding data in MOS transistors where the first annealing and the second annealing were both conducted by the conventional RTA using a halogen lamp (900° C., 10 milliseconds, and 1015° C., 10 milliseconds, respectively). Note that capacitance-voltage (CV) measurement for obtaining the results in FIG. 3A and FIG. 3B was carried out by applying an alternating voltage at 100 kHz between the semiconductor substrate 1 and the gate electrode 50 as shown in FIG. 3C.

As seen from FIG. 3A and FIG. 3B, in the case of Example 1, the gate capacitance is approximately 6×10⁻⁷ F/cm² at the gate voltage of 2.5 V. This value is almost equivalent to the gate capacitance of the MOS transistor fabricated by the conventional RTA using a halogen lamp, and the CV curve is almost the same. On the other hand, in the case of Comparative Example 1, the gate capacitance falls between approximately 2×10⁻⁷ and 3×10⁻⁷ F/cm² at the gate voltage of 2.5 V. In other words, the gate capacitance in Comparative Example 1 decreases less than half that in Example 1. This suggests that the insulator layer 3 under the gate electrode 50 of the transistor in Comparative Example 1 is thickly formed apparently. This can be considered to emanate from the fact that: activation of the impurities (P, B) implanted in the gate electrode 50 is carried out for a short time using a xenon flash lamp; thus diffusion of impurities (P, B) do not reach the bottom of the gate electrode 50; and thus a doped layer with insufficient concentration is formed at the bottom of the gate electrode 50. Assuming a step distribution of impurities, calculation of a deep region with zero impurity concentration in the gate electrode 50 from the actually measured gate capacitance is made; and according to this calculation result, that region is estimated to have a thickness of 20 nm or greater relative to the 175 nm-thick gate electrode 50.

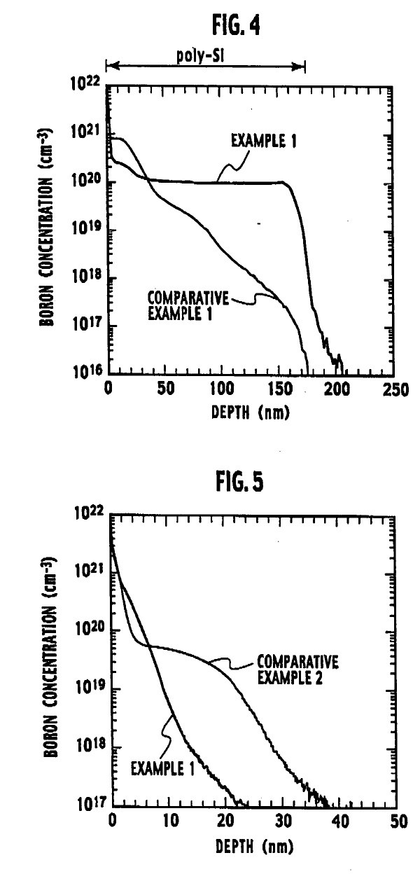

FIG. 4 shows a distribution of impurity concentration in the gate electrode 50, which is data supporting the above result FIG. 4 shows a distribution of impurity concentration along the depth of the gate electrode 50 formed on the pMOS region; where the horizontal axis indicates the depth of the gate electrode 50 (nm) and the vertical axis indicates the number density of boron atoms (cm⁻³). It is found from FIG. 4 that in the case of Example 1, boron atoms, which are impurities, are included almost uniformly in the 175 nm-thick gate electrode 50. On the other hand, in the case of Comparative Example 1, the impurity density in the gate electrode 50 varies; more specifically, the impurity density tends to gradually decrease from the surface to the bottom of the gate electrode 50. By contrast, the impurity density near the surface of the gate electrode 50 is higher than that of Example 1.

Depletion of carriers in the gate electrode 50 causes not only decrease in the driving force of each transistor, but also malfunction thereof. Therefore, a substantial solution is earnestly desired Comparative Example 2 is an example of attempting to control development of depletion layer in the gate electrode 50 by increasing the intensity of the flash lamp light than Comparative Example 1.

According to Comparative Example 2, although specific data is not shown here; CV characteristics similar to those in Example 1 were obtained, and development of depletion layer in the gate electrode 50 was able to be controlled to the same degree as with Example 1, owing to the increase in light intensity. However, the surface temperature of the semiconductor substrate 1 has been found to needlessly increase. This causes diffusion of impurities deeply in the extension regions 8 and 9, making it impossible to fabricate the MIS transistor in conformity with the design. FIG. 5 is a graph showing an impurity distribution in each of the semiconductor substrate 1 of Example 1 and of Comparative Example 2; where the horizontal axis indicates the depth of the semiconductor substrate 1 (nm) and the vertical axis indicates the concentration of implanted boron atoms (number of atoms/cm³). According to Comparative Example 2, the extension regions 8 and 9 extend to the vicinity of a 40 nm-deep region due to diffusion of impurity atoms.

As is found from the above findings, decreasing the irradiation energy of the flash lamp so as to control impurity diffusion in the semiconductor substrate 1 as with Comparative Example 1 may cause insufficient activation of the impurities in the gate electrode 50, resulting in development of a depletion layer in the gate electrode 50. On the other hand, increasing the irradiation energy of the flash lamp so as to effectively control development of depletion as with Comparative Example 2 may cause diffusion of the impurities in the semiconductor substrate 1. As a result, it is difficult to meet various demands of control of development of depletion layer in the gate electrode 50, activation of the impurity atoms in the semiconductor substrate 1, and formation of a shallowly diffused layer, only by means of adjusting the intensity of the flash lamp light.

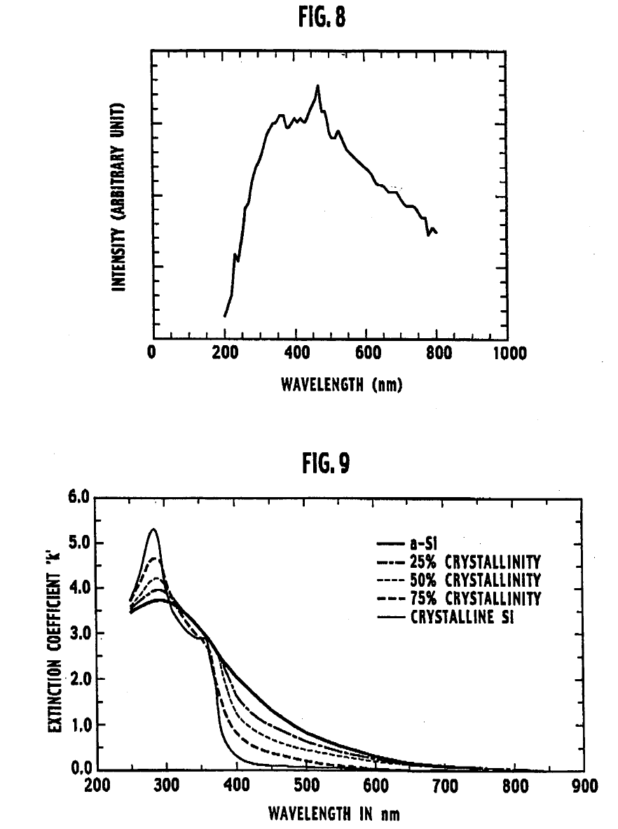

FIG. 8 is a graph showing a typical emission spectrum of a Xe flash lamp; where the horizontal axis indicates wavelength (nm) and the vertical axis indicates intensity (arbitrary unit). A light pulse emitted from the Xe flash lamp is a white light having energy between a near-ultraviolet region and a near-infrared region. On the other hand, FIG. 9 is a graph showing light absorbability for various silicon materials with different degrees of crystallinity (unit: %), which ranges from the near-ultraviolet region to the near-infrared region; where the horizontal axis indicates wavelength (nm), and the vertical axis indicates extinction coefficient (k). Assuming that λ denotes wavelength, the extinction coefficient k has a close connection with the following absorption coefficient α, which indicates light absorbability.
k=(λ/4π)α (1)

The light absorption characteristics of respective silicon materials are drastically different from each other due to the crystallographic quality thereof. As is seen from FIG. 9, as the degree of crystallinity increases or crystallographic quality of silicon material sequentially increases from the amorphous state thereof, the extinction coefficient decreases within the wavelengths ranging from 370 to 650 nm, and it increases within the short wavelengths of 300 n=or less. Focusing on a specific wavelength light, a light of 280 nm, for example, is most absorbable to a monocrystalline silicon. As the degree of crystallinity decreases, the absorbability decreases. The lights are least absorbable to silicon (a-Si) in an amorphous state. In addition, visible lights or lights of approximately 370 to 650 nm, for example, are most absorbable to the a-Si; and as the degree of crystallinity increases, the absorbability decreases. The visible lights are least absorbable to the monocrystalline silicon.

The MIS transistor fabrication method according to the first embodiment utilizes the difference in absorbable wavelength due to the difference in degree of crystallinity between the gate electrode 50 and the semiconductor substrate 1 to solve the conventional problems.

Lights of approximately 300 nm or less, more specifically, the lights in the vicinity of approximately 280 nm, for example, are difficult to be absorbed into a silicon material with incomplete crystallographic quality such as an amorphous silicon or a polycrystalline silicon to be used for the gate electrode 50, however, are easily absorbed into a silicon material with high crystallographic quality such as a monocrystalline silicon to be used for the semiconductor substrate 1. As a result, removal of short-wavelength lights from the irradiation lights 19 allows decrease in the amount of energy to be supplied to the semiconductor substrate 1.

On the other hand, lights of 300 nm or greater, more specifically, lights of 370 to 650 nm, for example, are easily absorbed into an amorphous silicon or a polycrystalline silicon with incomplete crystallographic quality to be used for the gate electrode 50, however, are difficult to be absorbed into a monocrystalline silicon with high crystallographic quality to be used for the semiconductor substrate 1. Accordingly, by removing only short-wavelength lights without removing such long-wavelength lights, the single wavelength irradiation light 19 or a flash lamp light is capable of adjusting the annealing effects on the gate electrode 50 with lower crystallographic quality and the semiconductor substrate 1 with higher crystallographic quality.

According to the first embodiment, annealing is carried out with a long wavelength light selected, which is easily absorbed into the gate electrode 50 made of a silicon material such as an amorphous silicon or a polycrystalline silicon with lower crystallinity than that of the semiconductor substrate 1. As a result, the MIS transistor fabrication method according to the first embodiment allows effective heating of the polycrystalline silicon layer 4, and hence suppression of gate depletion. Also in the semiconductor substrate 1, impurity diffusion is suppressed, thereby being able to obtain shallow diffusion regions with low resistivity.

One might consider another choice, that is, increase in acceleration energy of impurity ions when impurity ions are implanted into the gate electrode 50 so as to control gate depletion. If in some acceleration energy both of the projected range of ions in the polysilicon layer 4 and in the semiconductor substrate 1 could be controlled within respective suitable ranges, good results would be obtainable both in the formation of gate electrode 50 and in the substrate 1. However, ion implantation with increased acceleration energies has been found inevitably leading to the formation of deep extension regions 8, 9 and deep source and drain regions 14, which are not in suitable depths. In this case, diffusion also advances horizontally, resulting in generation of problems such as short-channel effects. Further, impurities may diffuse through the gate electrode 50 to an inner region of the gate oxide layer 3 or further to the surface of the semiconductor substrate 1 under the gate oxide layer 3. This causes another possibility of incurring a problem, changes in threshold voltage of the transistor.

The RTA processing using a halogen lamp can avoid development of depletion in the gate electrode 50 as described while referring to FIG. 3A and FIG. 3B. However, control of development of depletion layer in the gate electrode 50 is simultaneously not consistent with activation in the semiconductor substrate 1. Significant control of development of depletion layer by sufficient diffusion of impurities in the gate electrode 50 requires at least 10 seconds of annealing at a temperature of 1000° C. or higher using a halogen lamp. According to the recent MIS transistors which must achieve a shallow impurity projected range of several tens of nm, the pulse width of ten seconds is extremely long, resulting in significant diffusion of implanted impurities in extension regions 8, 9 and source and drain regions 14, 15, in a silicon semiconductor substrate 1. This causes the short-channel effects, resulting in malfunction of a transistor. Therefore, favorable results cannot be obtained after all, if not relying upon the method of fabrication of MIS transistors according to the first embodiment.

### Damage on Substrate

During annealing using flash lamp light, which is a short-time high-temperature process, the semiconductor substrate 1 is subjected to drastic increase and decrease in temperature and development of stress, and thus must withstands such harsh conditions. Therefore, it is desirable to carry out process evaluation in view of various damages developed on the semiconductor substrate 1, such as deformation, dislocation and stacking faults due to annealing.

The semiconductor devices obtained in Example 1 and Comparative Examples 1 and 2 were observed by a differential interference microscope and a transmission electron microscope (TEM) to evaluate deformation, dislocation, and stacking faults on the surface of the semiconductor substrate 1. As a result, no damage has been observed in Example 1, whereas a surface deformation which gives evidence of partial melting of a silicon, dislocation, and stacking faults have been observed in Comparative Examples 1 and 2.

Flash lamp light irradiates the impurity ion-implanted semiconductor substrate 1 so that the implanted impurity ions are activated. At this time, if the irradiation energy of the flash lamp light is too small those implanted impurity ions cannot be activated sufficiently. On the other hand, if the irradiation energy of the flash lamp light is too large damage may develop. Therefore, to subject the semiconductor substrate 1 to annealing by applying the flash lamp light, from the viewpoint of problems related to the diffusion of implanted impurity atoms as well as from the viewpoint of generation of damage, upper limits of the irradiation energy must be considered.

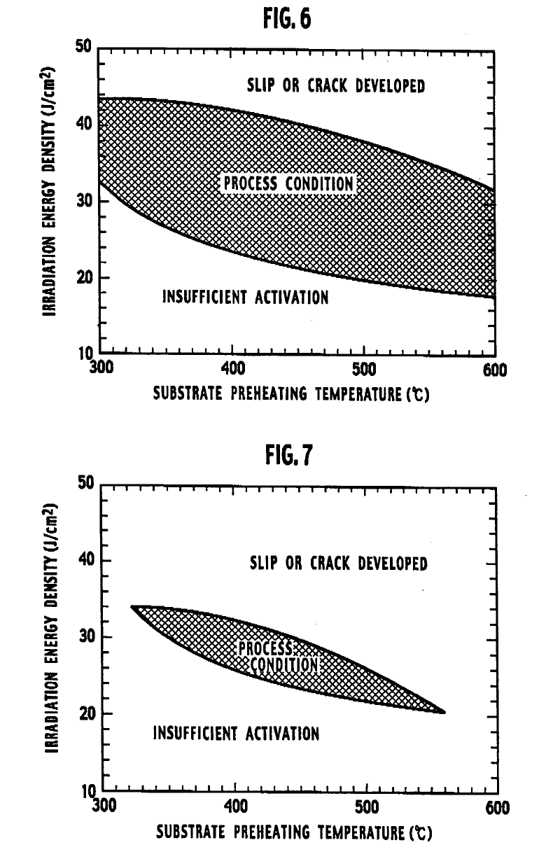

FIG. 6 shows an energy density range (process window) or an allowable range of irradiation (pulse width is one millisecond) of the semiconductor substrate 1 from the flash lamp light 19 to which wavelength selecting optical filter 7 is attached. The range is represented by the lowest limit, which is defined considering a requirement for activation, and the highest limit, which is defined considering prevention of damage. Note that the wavelength selecting optical filter 7 cuts off lights having wavelengths of 300 nm or less. Example 1 was conducted under the conditions of a semiconductor substrate 1 preheating temperature of 450° C. and an irradiation energy density of 35 J/cm². It is understood that the conditions fall within the process window shown in the drawing.

FIG. 7 shows the case where the pulse light 19 (with a pulse width of 1 millisecond) from the flash lamp to which the wavelength selecting optical filter 7 is not attached irradiates the semiconductor substrate 1. Comparative Example 1 was conducted under the conditions of a preheating temperature of 450°° C. and an irradiation energy density of 35 J/cm², and Comparative Example 2 was conducted under the conditions of a preheating temperature of 450°° C. and an irradiation energy density of 45 J/cm². Both conditions of Comparative Examples 1 and 2 are understood to be located above and outside of the process window.

According to FIGS. 6 and 7, the higher the preheating temperature, the smaller the irradiation energy required for activation, regardless of whether or not to use the wavelength selecting optical filter 7. However, it can be seen that the irradiation energy that develops damage in the semiconductor substrate 1 is reduced when the preheating temperature is made higher, at the same time. It should be noted further that the process window (process condition) is wider when using the wavelength selecting optical filter 7, with respect to the case where the wavelength selecting optical filter 7 is not used.

When using the flash lamp light 19 as shown in FIG. 8 for annealing without using the wavelength selecting optical filter 7, short-wavelength lights of 370 nm or less, lights for which a crystalline silicon has a high absorption coefficient, more specifically, a light of approximately 270 nm contributed to a critical point of the silicon (Si) band structure is mainly absorbed by the semiconductor substrate 1.

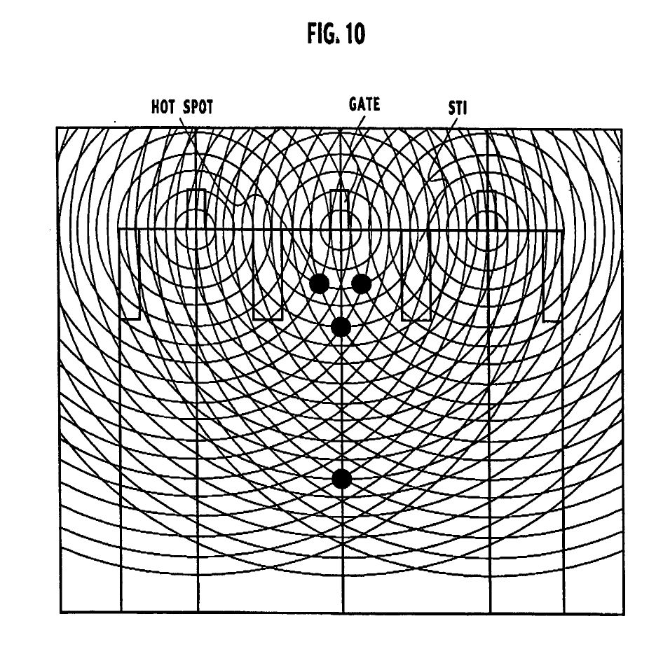

FIG. 10 is a diagram showing the outline of peaks and troughs of propagated waves when a single wavelength light refracts at device isolation regions such as shallow trench isolation (STI) and the polycrystalline silicon gate electrode 50, and locations of hot spots at which light energies concentrate due to interference of refracted waves at the gate electrode 50 and STI adjacent to each other. When flash lamp light is used as it is from the lamp light source, coherency of the light is high. As a result, hot spots shown in FIG. 10 develop in the semiconductor substrate 1, which may cause damage, such as crack, partial melting, sip, stacking faults, and dislocation, on the substrate due to annealing.

When wavelength selecting optical filter 7 is used, since annealing is carried out using lights in a gradually varying spectrum region (wavelengths between 370 and 650 nm), which avoids absorption coefficient significant points, light coherency in the semiconductor substrate 1 is reduced, thereby reducing development and intensity of hot spots, and preventing damage of the substrate 1.

The MIS transistor fabrication method according to the first embodiment provides depletion-controlled gates and a shallowly diffused region with high concentration without development of damage such as slip or a crack on the substrate. Furthermore, the condition range (process window) in which such good results are obtained is drastically expanded, hence stabilization of the process of fabrication. For this reason, according to the first embodiment of the present invention, miniaturized MIS transistors that can sufficiently utilize the LSI performance of next generation are fabricated.

### Second Embodiment

Typically, a semiconductor device fabrication method according to the second embodiment includes multiple annealing steps at different annealing temperatures and durations. Prior to formation of an extension region and deep source and drain regions, impurity ions are implanted in a polycrystalline silicon layer formed on the surface of a semiconductor substrate. Annealing is then carried out to form a gate electrode. It is desirable that annealing be carried out at a low temperature for a long time. Subsequently, an exposed surface of the semiconductor substrate is prepared; impurity ions are implanted in that exposed surface of the semiconductor substrate; and annealing is carried out using a high intensity flash lamp light for an extremely short time, so as to form an extension region and deep source and drain regions. Typically, the extension region and the deep source and drain regions arm formed in a self-aligned manner by impurity ion implantation, in the semiconductor substrate, using, as a mask, a gate electrode selectively formed on the surface of the semiconductor substrate or further a sidewall spacer formed on the sidewall of the gate electrode, and a subsequent annealing process to the semiconductor substrate.

The second embodiment is different from the first embodiment in that the second embodiment does not need to adjust wavelength distribution of a flash lamp light by use of a wavelength selecting optical filter. The second embodiment allows formation of a shallow impurity-diffused region with low resistivity and prevents polycrystalline gate electrode depletion.

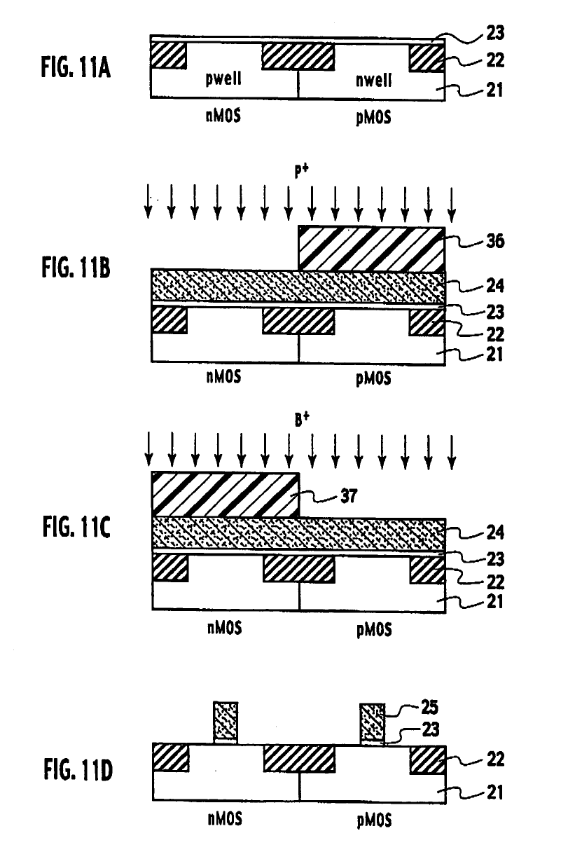

To begin with, as shown in FIG. 11A, a p-well region is formed in a region where an n-channel MOSFET is to be formed in a monocrystalline silicon semiconductor substrate 21 (hereafter, referred to as nMOS region), and an n-well region is formed in a region where a p-channel MOSFET is to be formed (hereafter, referred to as pMOS region) using a conventional CMOS transistor fabrication method. In addition, device isolator regions 22, such as silicon oxide layer filled STIS, are formed. A gate insulator layer 23, such as a silicon oxide film, is formed across the entirety of the semiconductor substrate 21 and the device isolator regions 22.

As shown in FIG. 11B, a polycrystalline silicon layer 24 is formed on the gate insulator layer 23. In addition, a photoresist film 36 is formed on the polycrystalline silicon layer 24 only on the pMOS region. Ions of Group-V atoms such as phosphorous ions (P) to be used as n-type impurities are ion-implanted in the polycrystalline silicon layer 24 of the nMOS region using the photoresist film 36 as a mask so as to achieve a concentration of 10¹⁹ cm⁻³ or greater (firs ion implantation in nMOS region).

After removal of the photoresist film 36, as shown in FIG. 11C, a photoresist film 37 is formed on the polycrystalline silicon layer 24 of the nMOS region. Group-III atoms such as boron atomic ions (B⁺) to be used as p-type impurities are ion-implanted in the polycrystalline silicon layer 24 of the pMOS region using the photoresist film 37 as a mask so as to reach a concentration of 10¹⁹ cm⁻³ or greater (first ion implantation in pMOS region).

After removal of the photoresist film 37 to expose the polycrystalline silicon layer 24, the polycrystalline silicon layer 24 and the gate insulator layer 23 are delineated using a highly directive etching method, such as a reactive ion etching (RIE) and photolithography. In addition, the polycrystalline silicon layer 24 is annealed to uniformly diffuse the implanted impurities in the entire polycrystalline silicon layer 24 (first annealing). As a result, as shown in FIG. 11D, a stacked-layer structure having the gate insulator layer 23 and the gate electrode 25, which are selectively formed on the semiconductor substrate 21, is obtained.

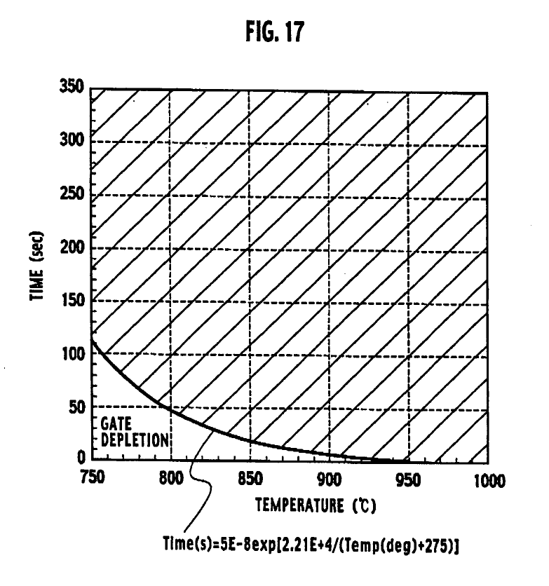

The first annealing may be carried out at a low temperature, such as 1000° C., for a long time period; such as for at least approximately ten seconds. Generally, desirable annealing conditions for uniform diffusion and activation, can be determined experientially. FIG. 17 shows the examples of annealing conditions determined by the inventors; where the horizontal axis indicates heating temperature T (° C.) and the vertical axis indicates annealing time t (second). A shaded region separated by a solid line represents an allowable range of energetically sufficient annealing conditions. Outside of that range, heating time period and/or heating temperature are insufficient, resulting in possible gate depletion. Accordingly, it is desirable to carry out annealing within at least the shaded region. The shaded region is also represented by the following expression:
t≧5×10⁻⁸ exp[2.21×10⁴/(T+275)] (2)

The first annealing may be carried out before the selective etching of the polycrystalline silicon layer 24 and the gate insulator layer 23. In this case, the polycrystalline silicon layer 24 and the gate insulator layer 23 are subjected to selective etching after annealing.

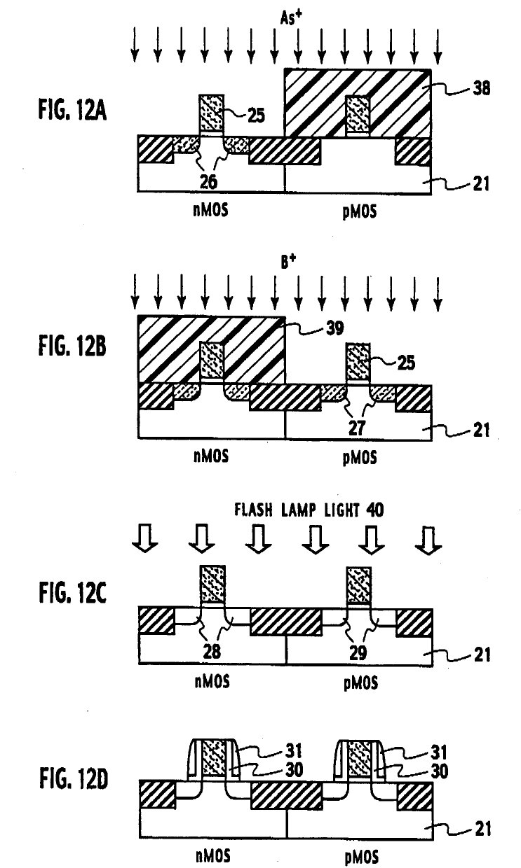

After the first annealing, as shown in FIG. 12A, a photoresist film 38 is delineated only on the pMOS region by photolithography. N-type impurity ions such as arsenic ions (As⁺) are implanted in the exposed nMOS region of the semiconductor substrate 21, using the photoresist film 38 and the gate electrode 25 on the nMOS region as a mask (second ion implantation in nMOS region). Impurity regions 26 adjacent to the edges of corresponding gate electrode 25 are formed in the nMOS region of the semiconductor substrate 21 through the second ion implantation. At this time, the ions are implanted also in the gate electrode 25 on the nMOS region.

After removal of the photoresist film 38, a photoresist film 39 is formed only on the nMOS region as shown in FIG. 12B. P-type impurity ions such as boron ions (B⁺) are implanted in the exposed pMOS region of the semiconductor substrate 21, using the photoresist film 39 and the gate electrode 25 on the pMOS region as a mask (second ion implantation in pMOS region). Impurity regions 27 adjacent to the edges of corresponding gate electrode 25 are formed in the pMOS region of the semiconductor substrate 21 through the second ion implantation. At this time, the ions are implanted also in the gate electrode 25 on the pMOS region.

After removal of the photoresist film 39, a second annealing is conducted by the irradiation of flash lamp light 40 from above the semiconductor substrate 21, as shown in FIG. 12C, while heating at approximately 450° C. A xenon flash lamp may be used as a flash lamp.

The second annealing activates implanted impurity ions, repairs the crystal defects in the impurity regions 26 and 27, and forms shallow source and drain regions (extension regions) 28 and 29 adjacent to the edges of corresponding gate electrode 25.

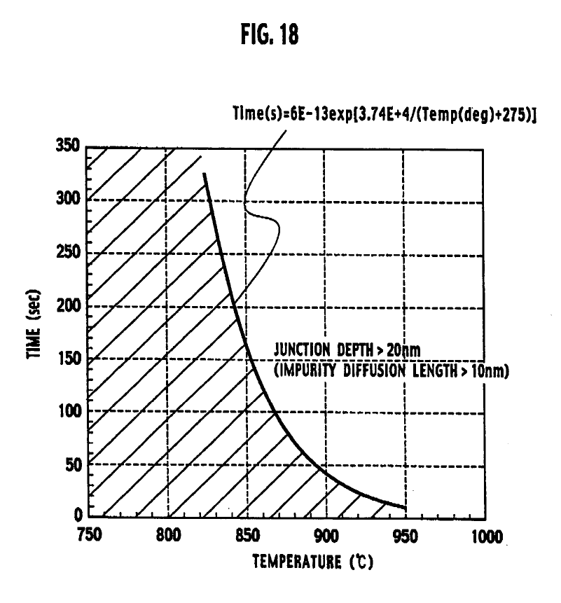

In order to activate implanted impurity ions to a high concentration, it is desirable that the second annealing be carried out by applying light from a flash lamp. Alternatively, the second annealing may be carried out using the RTA method that utilizes a halogen lamp. In this case, desirable annealing conditions are a substrate temperature of 900° C. or less and a heating period of time of 30 seconds or less. Examples of desirable second annealing conditions, which allow control of diffusion of impurities implanted in the semiconductor substrate, determined experientially by the inventors, are shown in FIG. 18. In the drawing, a shaded portion refers to a desirable condition range, and is represented by the following expression:
t≦6×10⁻¹³ exp[3.74×10⁴/(T+275)]. (3)

Use of the halogen lamp also prevents deep impurity diffusion in the semiconductor substrate, activate impurity atoms, repairs crystal defects of the impurity regions 26 and 27, and forms shallow source and drain regions 28 and 29.

After the second annealing, a silicon nitride (Si₃N₄) film 30 and a silicon oxide (SiO₂) film 31 are deposited in order on the entire surface of the substrate 21 using a film deposition method such as CVD. Subsequently, as shown in FIG. 12D, the silicon nitride film 30 and the silicon oxide film 31 are selectively left on the sidewalls of corresponding gate electrode 25 using a highly directive etching method, such as RIB, forming multilayer sidewall spacers.

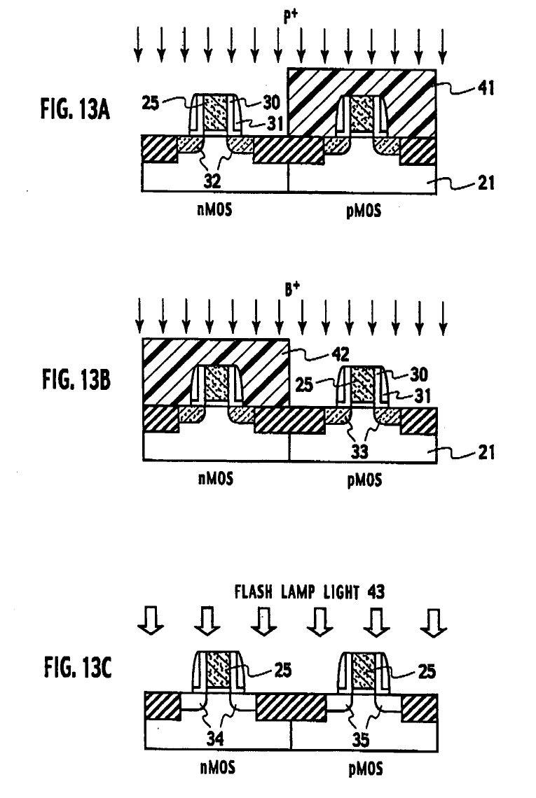

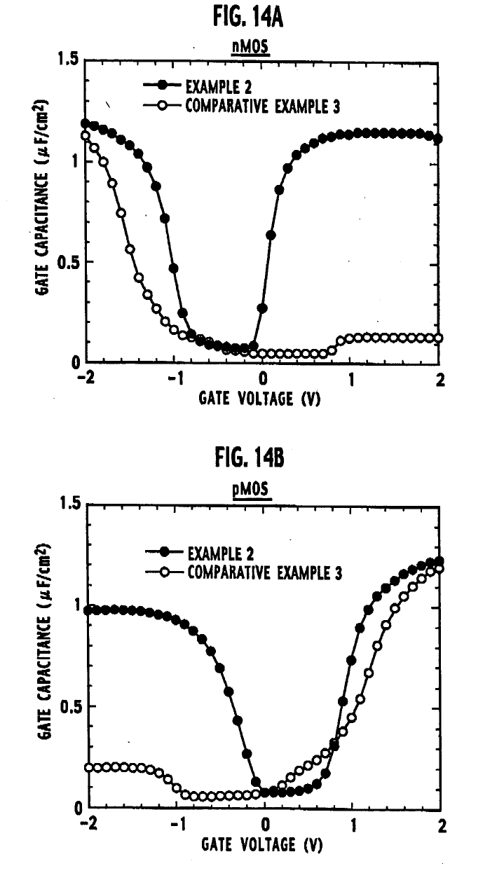

As shown in FIG. 13A, a photoresist film 41 is formed only on the pMOS region. Group-V ions such as P⁺ to be used as n-type impurities are ion-implanted in the nMOS region using as the photoresist film 41, the gate electrode 25 on the nMOS region, and the sidewall spacer including the selectively remaining silicon nitride film 30 and the silicon oxide film 31 as a mask (third ion implantation in nMOS region). Deep impurity regions 32 at certain intervals from the edges of corresponding gate electrode 25 are formed in the nMOS region through the third ion implantation.

After removal of the photoresist film 41, a photoresist film 42 is formed only on the nMOS region as shown in FIG. 13B. Group-III ions such as B⁺ to be used as p-type impurities are ion-implanted in the pMOS region using the photoresist film 42, the gate electrode 25 on the pMOS region, and the sidewall spacer including the silicon nitride film 30 and the silicon oxide film 31 as a mask (third ion implantation in pMOS region). Deep impurity regions 33 at certain intervals from the edges of corresponding gate electrode 25 are formed in the pMOS region through the third ion implantation.

After removal of the photoresist film 42, the flash lamp light 43 irradiates the entire surface of the substrate 21, gate electrode 25, and the sidewall spacer, as shown in FIG. 13C, which have been preheated at 450°° C., for example (third annealing). It is desirable to use a xenon lamp as a flash lamp. This light irradiation activates implanted impurity ions, repairs crystal defects at the impurity regions 32 and 33, and forms deep source and drain regions 34 and 35 at certain intervals from the edges of corresponding gate electrode 25.

Subsequent steps are not shown in the drawings, however, a silicon oxide film is formed on the entire surface of the semiconductor substrate 21 as an interlayer insulator film using the atmospheric pressure CVD method at a film formation temperature of 400° C., for example. Subsequently, contact holes are opened in the interlayer insulator film to form interconnects for a source and a drain electrode, and the gate electrode 25.

According to the MIS transistor fabrication method of the second embodiment of the present invention, impurities are implanted in the upper polycrystalline silicon layer 24, to form the gate electrodes 25, and are activated before implantation of impurities in the semiconductor substrate 21. This controls depletion in the gate electrode 25, formation of shallow impurity-diffused regions 28 and 29 with low resistivity, and sufficient diffusion and activation of the impurities in the gate electrodes 25, thereby accurately controlling impurity profiles. Therefore, stable and easy fabrication of high-performance, miniaturized MIS transistors is made possible.

### EXAMPLE 2

The second embodiment can be implemented under the following conditions:

The first ion implantation of P⁺ into the nMOS region was carried out by supplying an acceleration energy of 10 keV to P⁺ ions until the concentration of the atoms in the semiconductor substrate 21 reached 1×10²⁰ cm⁻³. On the other hand, the first ion implantation of B⁺ into the pMOS region was carried out by supplying an acceleration energy of 4 keV to B⁺ ions until the concentration of the atoms in the semiconductor substrate 21 reached 1×10²⁰ cm⁻³. In the first annealing, heating was cared out at 1000° C. for ten seconds by irradiating the semiconductor substrate 21 with the halogen lamp light from above substrate 21.

The second ion implantation of As⁺ was carried out under the conditions of an acceleration energy of 1 keV and a dose amount of 1×10¹⁵ cm⁻², and second ion implantation of B⁺ was carried out under the conditions of an acceleration energy of 0.2 keV and a dose amount of 1×1015 cm⁻². The second annealing was carried out with a substrate preheated temperature of 450°° C., a xenon flash lamp light irradiation time of 1 millisecond, and an energy density of 28 J/cm².

The third ion implantation of P⁺ into the nMOS region was carried out under the conditions of an acceleration energy of 15 keV and a dose amount of 3×10¹⁵ cm⁻², and third ion implantation of B⁺ into the pMOS region was carried out under the conditions of an acceleration energy of 4 keV and a dose amount of 3×10¹⁵ cm⁻². The third annealing was carried out with a substrate preheated temperature of 45° C., a xenon flash lamp light irradiation time of 1 millisecond, and an energy density of 28J/cm². The film thickness of the gate electrode 25 of the fabricated MOS transistor was 150 nm.

### COMPARATIVE EXAMPLE 3

A semiconductor device was fabricated by the same steps as those with Example 2 except that the first ion implantation was not carried out.

FIG. 14A and FIG. 14B show the gate capacitance of the MOSFET according to each of Example 2 and Comparative Example 3; where the horizontal axis indicates gate voltage (V) and the vertical axis indicates gate capacitance (mF/cm²). FIG. 14A shows the n-channel MOSFET measurement results, while FIG. 14B shows the p-channel MOSFET measurement results; either result is obtained by applying AC voltage with a frequency of 100 kHz between corresponding gate electrode 25 and the semiconductor substrate 21.

As is shown in FIG. 14A and FIG. 14B, in the case of the n-channel MOSFET, when the gate voltage is +1.5 V, for example, the gate capacitance of Example 2 is approximately 1.1 mF/cm², whereas that of Comparative Example 3 to extremely low at 0.13 mF/cm². Similarly, in the case of the p-channel MOSFET, when the gate voltage is −1.5 V, for example, the gate capacitance of Example 2 is approximately 1.0 mF/cm², whereas that of Comparative Example 3 is 0.2 mF/cm².

These results suggest that the gate insulator layer 23 in Comparative Example 3 is apparently thickly formed since the first ion implantation is not carried out. This can be considered to emanate from the fact that: activation of the impurities (P, B) implanted in the gate electrode 50 is carried out for too short a period of time using a xenon flash lamp. Thus diffusion of impurities (P, B) does not extend to the bottom of the polycrystalline silicon layer 24; and thus a doped layer with insufficient concentration is formed at a lower portion of the polycrystalline silicon layer 24. Assuming a step distribution of impurities, a calculation of a deep region with substantially zero impurity concentration in the gate electrode 25 from the actually measured gate capacitance is made; and according to this calculation result, that region is estimated to have a thickness of at least 20 nm relative to the 150 nm-thick gate electrode 25.

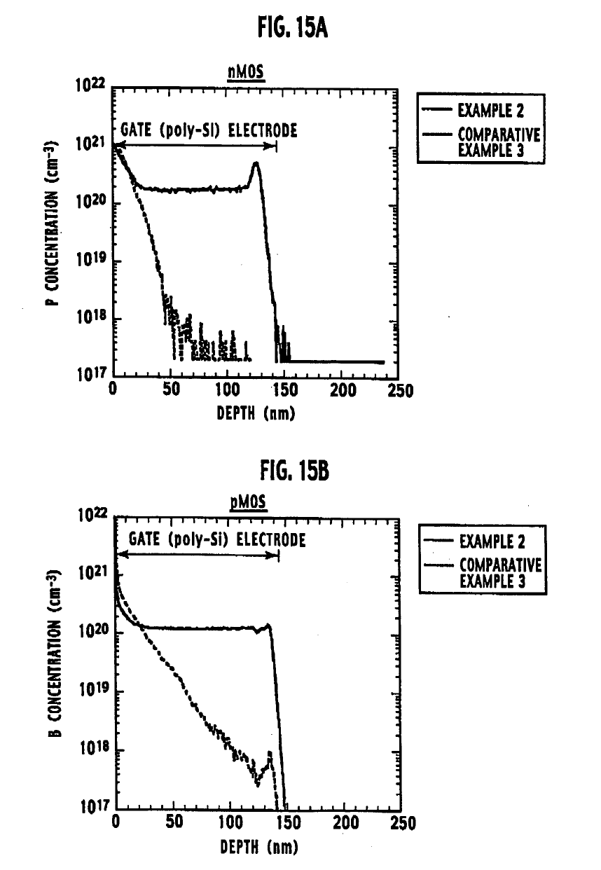

In addition, a distribution of impurity concentration in the gate electrode 25 was examined with Secondary Ion Mass Spectrometry (SIMS) in order to support the above findings. The results are shown in FIG. 15A and FIG. 15B. FIG. 15A and FIG. 15B show a distribution of impurity atoms in a gate electrode 25; where the horizontal axis indicates depth in the gate electrode 25 or the distance from the top thereof (nm), and the vertical axis indicates impurity concentration (cm⁻³). FIG. 15A is data regarding the n-channel MOSFET. FIG. 15B is data regarding the p-channel MOSFET.

As is understood from FIG. 15A and FIG. 15B, in the case of Example 2, phosphorus or boron impurities, are almost uniformly distributed in the gate electrode 25 with a film thickness of 150=n, except for the significant points near the interface in contact with the gate insulator layer 23 and near the surface of the gate electrode 25. On the other hand, according to Comparative Example 3, the impurity concentration of the gate electrode 25 is unstable and tends to gradually decrease from near the surface to near the interface in contact with the gate insulator layer 23. Such decrease in the impurity concentration of the gate electrode 25 causes depletion in the gate electrode 25, which brings about a substantial increase in the film thickness of the gate insulator layer 23, adversely influencing the electrical characteristics of the transistor.

Note that the third annealing is carried out without using RTA with a halogen lamp, but using a flash lamp. However, it is unnecessary to change wavelengths using a wavelength selecting optical filter as with the case of the first embodiment. To carry out the third annealing or the RTA using a halogen lamp so that depletion in the gate can be controlled and that a desired resistance value for the gate electrode 25 can be obtained, an annealing temperature of 1000° C. or greater and a heating time period of at least 10 seconds are recommended

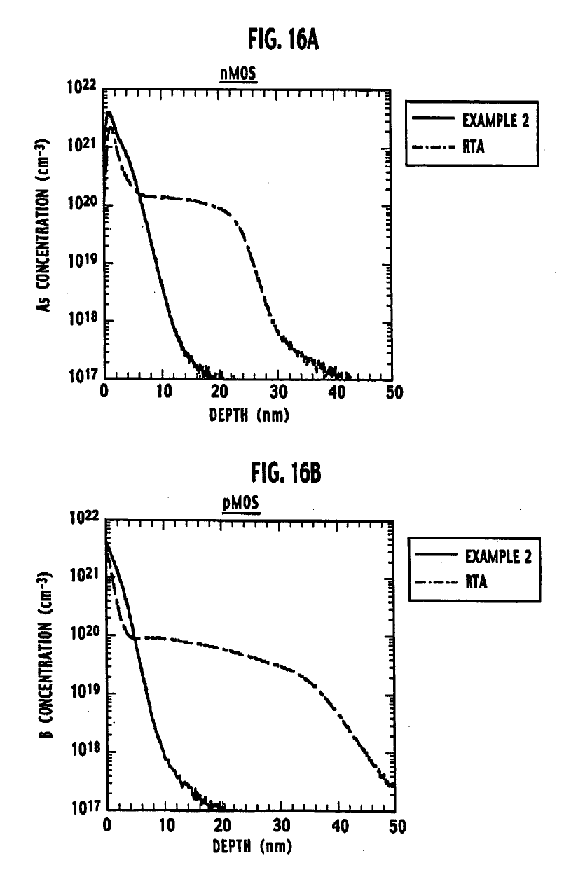

FIG. 16A and FIG. 16B show impurity concentration profiles in extension regions, for the case of Example 2 and for the case where the third annealing was conducted by RTA using a halogen lamp. FIG. 16A shows the case of an cannel MOSFET, and FIG. 16B shows the case of a p-channel MOSFET, where the horizontal axis indicates depth from the surface of the semiconductor substrate 21 (nm), and the vertical axis indicates impurity ion concentration (cm⁻³). In the case of the RTA using a halogen lamp, the heating period of time is 10 seconds, which is extremely longer than the case of at least Example 2. Therefore, shallowly implanted impurity atoms further diffuse into a deeper region within that duration of time, making the depth of the extension region at least twice.

According to the second embodiment, before ion implantation of impurities into the monocrystalline silicon semiconductor substrate 21, impurities are ion-implanted in advance in the polycrystalline silicon layer 24 formed on the semiconductor substrate 21 to sufficiently diffuse and activate the impurities. Subsequently, the impurities in the semiconductor substrate 21 are activated in a short time using a flash lamp light. This controls the impurity junction depth in the extension region (a region where the impurity ion concentration is approximately 10¹⁸ cm⁻³ or greater) to be 20 nm or less; decreases the resistance of the diffusion layer, and prevents gate electrode depletion.

The second embodiment prevents gate depletion and educes the influence of the short-channel effect. In addition, easy fabrication of a minute MIS transistor, which enhances the performance of next generation LSIs, is possible.

The present invention is described in various embodiments. However, the present invention is not limited to those embodiments, and various changes are allowed within a range not deviating from the scope of the invention.

For example, in the first embodiment, the present invention is described as applied to a method of forming gate electrode 25 and a method of forming source and drain diffused regions 34, 35. However, the present invention is not limited to this, and can be applied to a method of forming a channel region or forming a gate oxide film, or other steps which require annealing. In addition, the annealing device using a flash lamp as a light source is described; however, the present invention is not limited to this, and it is naturally applicable to the case of using a light source which illuminates between the visible light region and the ultraviolet region.

Furthermore, in the first embodiment, an optical filter is used as a wavelength selecting means; however, the amount of gas charged in the flash lamp, used as a light source, may be adjusted by any suitable means. In other words, a relationship between the amount of charged gas in the flash lamp and the emitted light wavelength characteristics is understood to determine the wavelength characteristics of the light required for annealing for the semiconductor substrate, and the amount of gas to be charged in the flash lamp is then determined from the wavelength characteristics. A method of using a flash lamp as a light source in which a determined amount of gas is to be charged, falls within the scope of the present invention.

In the second embodiment, after formation of a polycrystalline silicon layer into which no impurity is doped, the n-type impurities and the p-type impurities are ion-implanted in the nMOS region and the pMOS region, respectively, forming a gate electrode. Alternatively, the pMOS region may be changed from n-type to p-type conductivity by doping P⁺ into the entire surface of the semiconductor substrate when forming the polycrystalline silicon layer, and then ion-implanting B⁺ only in the pMOS region. Alternatively, the nMOS region may be changed from p-type to n-type conductivity by doping B⁺ into the entire surface of the semiconductor substrate in advance, and then ion-implanting P⁺ only in the nMOS region.

In addition, light sources other than the flash lamp may be used. Light sources other than the Xe lamp, such as an excimer laser, a YAG laser, a metal halide lamp, a Kr lamp, a mercury lamp, or a hydrogen lamp may be used. When using the YAG laser or the excimer laser, the same wavelength selectivity as that for the wavelength selecting optical filter may be given to the projected light by a dye laser, which uses such laser as an excitation source. It is desirable to use a light source in which the irradiation time can be adjusted to be 100 milliseconds or less, more desirably, 10 milliseconds or less.

1. A method for manufacturing a semiconductor device, comprising:
forming an insulator layer on a crystalline silicon substrate;
forming selectively a silicon layer on the insulator layer, the silicon layer being lower in degree of crystallinity relative to the substrate;
implanting impurity ions tar surfaces of the substrate and the silicon layer so as to form impurity regions in the substrate in a self-aligned manner;
generating a light pulse substantially having a wavelength in a range between 370 and 700 nm; and,
forming source and drain regions, and a silicon-gate electrode, through activation of implanted ions in the impurity regions and in the silicon layer, respectively, by common irradiation of the light pulse to the surfaces of the substrate and the silicon layer.

2. The method of claim 1, wherein the silicon layer is a polycrystalline silicon layer.

3. The method of claim 1, wherein the light pulse is generated with a light source selected from the group consisting of an excimer laser, a YAG laser, a metal halide lamp, a Kr lamp, a mercury lamp, a hydrogen lamp, and a flash lamp.

4. The method of claim 1, wherein the wavelength of the light pulse is modulated through a dye laser, using an excimer laser or a YAG laser as an excitation light source.

5. The method of claim 1, wherein the light pulse has a pulse width between 0.1 and 100 milliseconds.

6. The method of claim 1, wherein the light pulse is irradiated to the substrate at a temperature of 600° C. or less.

7. A method for manufacturing a semiconductor device, comprising:
forming an insulator layer on a crystalline silicon substrate:
forming selectively a silicon layer on the insulator layer, the silicon layer being lower in degree of crystallinity relative to the substrate;
implanting impurity ions to surfaces of the substrate and the silicon layer so as to form impurity regions in the substrate in a self-aligned manner;
generating a light pulse from a flash lamp light, by relative reduction of energy of the flash lamp light, in a wavelength of 370 nm or less, relative to the wavelength larger than 370 nm; and,
forming source and drain regions, and a silicon-gate electrode, through activation of impurity ions in the impurity regions and in the silicon layer, respectively, by common irradiation of the light pulse to the surfaces of the substrate and the silicon layer.

8. The method of claim 7, wherein the relative reduction is conducted by making the flash lamp light passed through an optical filter.

9. The method of claim 7, wherein the relative reduction is conducted through adjustment of gas pressure in a flash lamp used to generate the flash lamp light.

10. The method of claim 7, wherein the silicon layer is a polycrystalline silicon layer.

11. The method of claim 7, wherein the light pulse has a pulse width between 0.1 and 100 milliseconds.

12. The method of claim 7, wherein the light pulse is irradiated to the substrate at a temperature of 600° C. or less.

13. A method for manufacturing a semiconductor device, comprising;
forming on a substrate an insulator layer and a silicon layer on the insulator layer, the substrate being made of crystalline silicon and the silicon layer being lower in degree of crystallinity relative to the substrate;
forming a doped-silicon gate structure by implanting impurity ions to the silicon layer, activation of implanted ions and selective etching of the silicon layer and the insulator layer;
implanting impurity ions to a surface of the substrate so as to form impurity regions in the substrate in a self-aligned manner; and,
forming source and drain regions through activation of the implanted ions in the impurity regions by irradiation of a light pulse to the surface of the substrate.

14. The method of claim 13, wherein the light pulse is a flash lamp light.

15. The method of claim 13, wherein the silicon layer is a polycrystalline silicon layer.

16. The method of claim 13, wherein the light pulse has a pulse width between 0.1 and 100 milliseconds.

17. The method of claim 13, wherein the light pulse is irradiated to the substrate at a temperature of 600° C. or less.

18. The method of claim 13, wherein the activation of implanted ions in the silicon layer is carried out under the following condition:
t≧5×10⁻⁸ exp[2.21×104/(T+275)],
where T indicates a temperature of the silicon layer, and t indicates a time period for the activation.
